(19) United States
(12) Patent Application Publication
(10) Pub. No.: US 2019/0036526 A1
(43) Pub. Date: Jan. 31, 2019

(54) ELECTRONIC CIRCUIT COMPRISING A SWITCHING MEANS

(71) Applicant: Kone Corporation, Helsinki (FI)

(72) Inventors: Juhamatti NIKANDER, Helsinki (FI); Arto NAKARI, Helsinki (FI)

(73) Assignee: Kone Corporation, Helsinki (FI)

(21) Appl. No.: 16/035,830

(22) Filed: Jul. 16, 2018

(30) Foreign Application Priority Data
Jul. 25, 2017 (EP) 17183072.2

(51) Int. Cl. H03K 17/693; H02H 7/122; H02P 8/34

(52) U.S. Cl. CPC H03K 17/693; H02P 8/34; H02H 7/1227

(57) ABSTRACT

The invention relates to an electronic circuit comprising a switching means, having a monitoring circuit to monitor the switching status of the switching means. According to the invention the switching means comprises at least one semiconductor switch as a switching element, which semiconductor switch is connected to a gate driver which is controlled by a control signal (C) to effect switching of the semiconductor switch, the gate driver being supplied by a gate driver power supply, whereby the monitoring circuit is arranged between the semiconductor gate and its collector and comprises a series connection of an opto-coupler, a current-limiting resistor and a protection diode, which series connection is connected in series with the gate driver power supply.

This application claims priority to European Patent Application No. EP171830722 filed on Jul. 25, 2017, the entire contents of which are incorporated herein by reference.

The present invention relates to an electronic circuit comprising a switching means. Circuits of this kind are used for example in motor or brake drives of passenger conveyors as elevators and escalators to separate the motor drive or brake drive from mains. This switching means are usually realized by a relay which is controlled by a control signal of a safety circuit of the passenger conveyor. If any situation occurs wherein the safety does not meet the machine specific safety requirements, the relay is opened and the motor drive or brake drive is separated from mains. It is further important for the passenger conveyor to get information about the status of this safety relay. On this behalf, the electronic circuit comprises a monitoring circuit which gives information about the status of the switching means, i.e. the relay. Via the output signal of the monitoring circuit, the device, for example the escalator or elevator, knows whether or not the corresponding drive has been correctly separated from mains or not.

The conventional switching relays with the corresponding monitoring circuit are reliable and are comparably easily to install. A disadvantage of these components is that switching relays are prone to wear and the switching relays are comparably expensive.

It is therefore target of the present invention to provide an electronic circuit comprising a switching means with status monitoring according to the above-mentioned type which is cheaper and which is easy to install and reliable in its operation.

This object is solved with an electronic circuit according to claim 1. Preferred embodiments of the invention are subject-matter of the dependent claims. Preferred embodiments of the invention are also described in the descriptive part of the application as well as in the drawings.

According to the invention, the switching means comprises at least one semiconductor switch as the switching element, which semiconductor switch is connected to a gate driver which is controlled by a control signal to effect switching of the semiconductor switch. The gate driver is connected to a gate drive power supply. According to the invention the monitoring circuit is arranged between the semiconductor gate and its collector and it comprises a series connection of an opto-coupler, a current-limiting resistor and a protection diode, which series connection is connected in series with the gate driver power supply.

Thereby, the series diode blocks monitoring current flowing to external circuits. The LED of the opto-coupler will be off when the transistor is in a non-conducting state (OFF) and the LED is on when the transistor is in a conducting state (ON). Thus, the signal output of the opto-coupler will give reliable information about the switching status of the semiconductor switch whereby the whole circuit is comparably cheap, is easy to install and has an essentially longer lifetime than conventional switching relays.

Preferably, the current-limiting resistor is of a MELF-type to avoid the bypassing of the transistor through the gate power supply and the monitoring circuit in case the transistor is broken.

Preferably, the semiconductor switch is a transistor which is commercially available and which is reliable for said purpose.

In a preferred embodiment of the invention, a parallel diode is connected in parallel, preferably antiparallel, to the semiconductor switch. This feature avoids the monitoring current supplied by the gate drive power supply from powering the load which is switched by the semiconductor switch.

Preferably, a coupler diode is connected in parallel to the opto-coupler to avoid damaging of the opto-coupler by external load peaks which are not generated by the gate driver power supply.

Preferably, the electronic circuit is part of a motor drive and/or brake drive of a passenger conveyor which might be an escalator or elevator or moving ramp or the like. Particularly in these drives, the use of the electronic circuit as a separation circuit for separating the corresponding drive from mains is a very advantageous measure as the currently used switching relays are subject to wear and are quite expensive. Therefore, the use of the electronic circuits in these drives is particular advantageous.

Preferably, the electronic circuit is part of a motor drive comprising a rectifier bridge connected to mains and an inverter bridge connected with a passenger conveyor motor. The rectifier bridge and the inverter bridge are connected via a DC link and the switching means are arranged in a connection between the rectifier bridge and mains. The arrangement of the above-mentioned electronic circuit in this connection is preferably advantageous as high currents are switched which lead to a fast wear of the currently used relays because sometimes the motor drive may be switched off during a high current period which might even lead to lightning sparks when switching off. The switching of the motor drive via the semiconductor switches (normally three semiconductor switches have to be used as switching means, one for each phase) does not lead to any lightning sparks when switching the motor drive on or off.

In an alternative preferred embodiment of the invention the monitoring circuit is configured to indicate fault of the switching means, if the opto-coupler is conducting when the control signal is in OFF-state. Accordingly, the invention is able monitor different fault modes as usually IGBT desaturation circuits indicate a fault in case the opto-coupler is not conducting when the control signal is in ON-state.

The invention also refers to a brake drive and/or motor drive with an electronic circuit according to the above specification as well as to a passenger conveyor with a brake drive and/or motor drive of an electronic circuit according to the above-mentioned type whereby a particular cost-saving is obtained as in connection with a motor drive or brake drive of a passenger conveyor comparably high currents are switched which lead to a fast wear of conventional relay switches.

It is clear for the skilled person that the above-described embodiments may be combined with each other arbitrarily.

The invention will be described hereinafter by means of an embodiment in connection with the enclosed drawing.

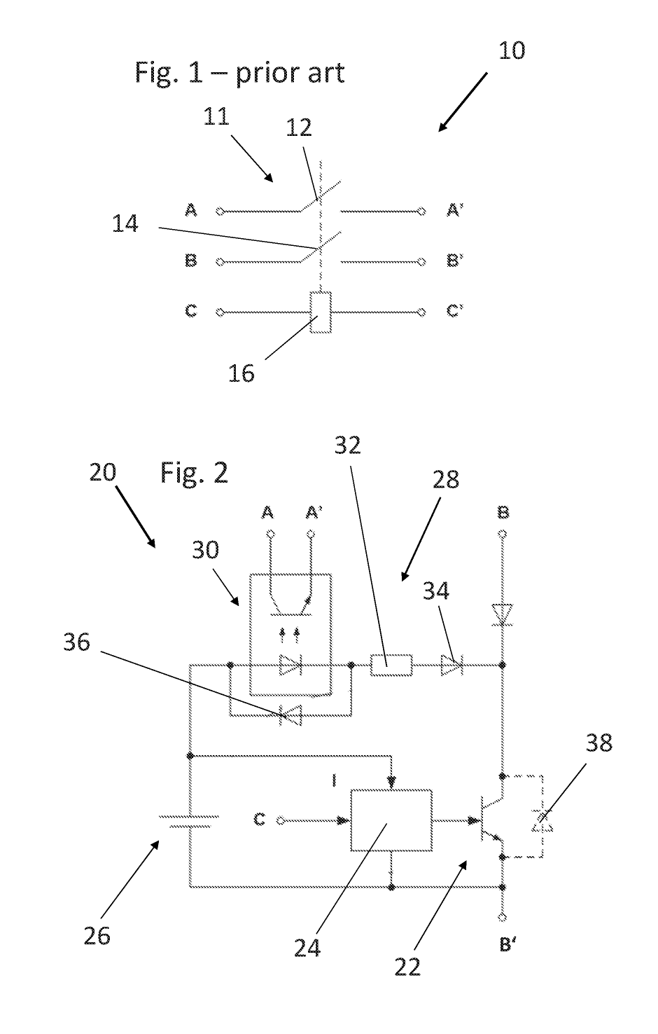

FIG. 1 shows a prior art switching means formed by a relay switch, and

FIG. 2 shows an electronic circuit comprising an electronic circuit according to the present invention.

FIG. 1 shows an input section 10 of a motor or brake drive having a switching relay 11 with relay switches 12, 14 which relay switches 12, 14 are activated by a solenoid 16 which is controlled by a control signal C for example of a safety device of an escalator or elevator and which further provides a monitoring signal about the switching status of the relay switches 12, 14. The disadvantage of this currently used switching relay is that it is prone to wear and that it is comparably expensive. As the switching relay switches in a motor drive or brake drive of an elevator or escalator, comparably high currents also lightning sparks may occur at the relay switches 12, 14 which accelerate the wear of the switching relay and affect the reliability of this switching means in total.

The present invention offers a new type of electronic switching circuit 20 comprising a semiconductor switch 22, preferably in form of a transistor. The transistor is connected between a connection point B, for example a rectifier bridge of a motor drive and another connection point B′ for example one phase of mains. The transistor 22 is controlled by a gate driver 24 which is powered by a gate driver power supply 26. The gate driver 24 is controlled by a control signal C. Connected in series with the gate driver power supply, a monitoring circuit 28 is provided which comprises a series connection of an opto-coupler 30, a current limiting resistor 32 and a protection diode 34. Optionally, a coupler diode 36 may be connected in parallel to the opto-coupler 30. The current limiting resistor 32 and the protection diode 34 ensure that the opto-coupler is driven in a safe operating condition without current peaks and without load signals from external sources (for example the load B) flowing through the opto-coupler. Via this measure, it is ensured that the opto-coupler is really only driven by the gate driver power supply and the gate driver 24 thus ensuring that the on/off state of the opto-coupler with its outputs A and A′ is only dependent on the switching status of the semiconductor switch 22.

Advantageously, a parallel diode 38 is connected antiparallel to the semiconductor switch, e.g. transistor 22 to avoid that the monitoring current supplied by the gate driver power supply has an effect on the load itself.

If the current limiting resistor 32 is of a MELF-type, the bypassing of the transistor through the gate driver power supply and the monitoring circuit is avoided in case the semiconductor switch or transistor 22 is broken.

Via this advantageous electronic circuit 30, on one hand a secure and reliable switching even of high currents is obtained with the semiconductor switch 22 and on the other hand the monitoring circuit 30 enables a reliable output signal A, A′ of the opto-coupler 30 dependent only on the switching status of the semiconductor switch 22 to monitor its switching state.

The invention is not restricted to the embodiments specified above but may be varied within the scope of the appended patent claims.

### TABLE OF REFERENCE NUMBERS

10 input section of a drive
11 switching relay
12 first relay switch
14 second relay switch
16 solenoid of the switching relay
20 inventive electronic switching circuit
22 semiconductor switch—transistor
24 gate driver
26 gate driver power supply
28 monitoring circuit
30 opto-coupler
32 current limiting resistor
34 protection diode
36 coupler diode
38 (anti)parallel diode

1. Electronic circuit comprising a switching means, having a monitoring circuit to monitor the switching status of the switching means, characterized in that the switching means comprises at least one semiconductor switch as a switching element, which semiconductor switch is connected to a gate driver which is controlled by a control signal (C) to effect switching of the semiconductor switch, the gate driver being supplied by a gate driver power supply, whereby the monitoring circuit is arranged between the semiconductor gate and its collector and comprises a series connection of an opto-coupler, a current-limiting resistor and a protection diode, which series connection is connected in series with the gate driver power supply.

2. Electronic circuit according to claim 1, wherein the current-limiting resistor is of a MELF-type.

3. Electronic circuit according to claim 1, wherein the semiconductor switch is a transistor.

4. Electronic circuit according to claim 1, wherein a parallel diode is connected anti-parallel to the semiconductor switch.

5. Electronic circuit according to claim 1, wherein a coupler diode is connected in parallel to the opto-coupler.

6. Electronic circuit according to claim 1, which is part of a motor drive and/or brake drive of a passenger conveyor, particularly of an escalator or elevator.

7. Electronic circuit according to claim 4, which is part of a motor drive comprising a rectifier bridge connected to mains and an inverter bridge connected with a passenger conveyor motor, which rectifier bridge and inverter bridge are connected via a DC link, whereby the semiconductor switch is arranged in a connection between the rectifier bridge and mains.

8. Electronic circuit according to claim 1, wherein the monitoring circuit is configured to indicate fault of the switching means, if opto-coupler is conducting when control signal (c) is in OFF-state.

9. Brake drive and/or motor drive with an electronic circuit according to claim 1.

10. Passenger conveyor with a brake drive and/or motor drive according to claim 9.
